(19) United States
(12) Patent Application Publication
(10) Pub. No.: US 2025/0059645 A1
(43) Pub. Date: Feb. 20, 2025

(54) SUBSTRATE PROCESSING DEVICE, AND METHOD FOR MANUFACTURING METAL OXIDE SEMICONDUCTOR

(71) Applicant: JUSUNG Engineering Co., Ltd., Gwangju-si, Gyeonggi-do (KR)

(72) Inventors: Duck Ho KIM, Yongin-si Gyeonggi-do (KR); Min Hyuk KIM, Yongin-si Gyeonggi-do (KR); Kyung In MIN, Yongin-si Gyeonggi-do (KR); Chang Kyun PARK, Yongin-si Gyeonggi-do (KR); Jun Hee HAN, Yongin-si Gyeonggi-do (KR); Du Ho KIM, Yongin-si Gyeonggi-do (KR); Su Ye KIM, Yongin-si Gyeonggi-do (KR); Seung Hyun LEE, Yongin-si Gyeonggi-do (KR); Chul Joo HWANG, Yongin-si Gyeonggi-do (KR)

(21) Appl. No.: 18/721,190

(22) PCT Filed: Jan. 17, 2023
(86) PCT No.: PCT/KR2023/000800

§ 371 Date: Jun. 17, 2024

(30) Foreign Application Priority Data
Jan. 27, 2022 (KR) 10-2022-0011890
Oct. 26, 2022 (KR) 10-2022-0139067

(51) Int. Cl. C23C 16/455; C23C 16/40; C23C 16/44; C23C 16/52; H01J 37/32; H01L 27/06; H01L 27/12; H01L 29/786

(52) U.S. Cl. CPC C23C 16/45544; C23C 16/407; C23C 16/4408; C23C 16/45536; C23C 16/45553; C23C 16/52; H01L 27/0688; H01L 27/1225; H01L 29/7869; H01J 37/32449

(57) ABSTRACT

A substrate processing device. The device comprises: a first source supply unit; a second source supply unit; a first supply line for connecting the first source supply unit to a spraying unit; a second supply line for connecting the second source supply unit to the spraying unit; a mixing unit provided at the first supply line to be arranged between the first source supply unit and the spraying unit; a first connection line for connecting the second supply line to the first supply line and/or the mixing unit; and a first path change unit provided at a first connection point at which the first connection line is connected to the second supply line, wherein the first path change unit changes the flow path of a second source gas supplied from the second source supply unit.

### TECHNICAL FIELD

The present invention relates to a substrate processing apparatus which performs a processing process such as a deposition process and an etching process on a substrate.

### BACKGROUND ART

Generally, a thin-film layer, a thin-film circuit pattern, or an optical pattern should be formed on a substrate for manufacturing a solar cell, a semiconductor device, a flat panel display device, etc. To this end, a processing process is performed on a substrate, and examples of the processing process include a deposition process of depositing a thin film including a specific material on the substrate, a photo process of selectively exposing a portion of a thin film by using a photosensitive material, an etching process of removing the selectively exposed portion of the thin film to form a pattern, etc.

Such a processing process on a substrate is performed by a substrate processing apparatus. The substrate processing apparatus performs the processing process on the substrate by using a gas supplied from a gas supply apparatus.

FIG. 1 is a schematic block diagram of a substrate processing apparatus according to the related art.

Referring to FIG. 1, a substrate processing apparatus 10 according to the related art includes an injection unit 11 which injects a gas toward a substrate, a first supply unit 12 which supplies a first gas to the injection unit 11, and a second supply unit 13 which supplies a second gas to the injection unit 11. The first gas supplied by the first supply unit 12 and the second gas supplied by the second supply unit 13 are mixed with each other in a mixing space disposed in the injection unit 11, and then, are injected toward the substrate.

Here, because a gas flow path for enabling the first gas and the second gas to flow should be provided in the injection unit 11, the mixing space is implemented to be narrow. Therefore, in the substrate processing apparatus 10 according to the related art, it is difficult to control a mixing composition ratio of the first gas and the second gas, and due to this, a deviation of the mixing composition ratio of the first gas and the second gas increases, whereby there is a problem where the film quality of a thin film formed by using the first gas and the second gas is degraded.

### SUMMARY

The present invention is devised to solve the above-described problem and is for providing a substrate processing method which may enhance the film quality of a thin film formed by using a first gas and a second gas.

The present invention is for providing a method of manufacturing a metal oxide semiconductor, which may improve a step coverage of an oxide layer including gallium.

### Technical Solution

To accomplish the above-described objects, the present invention may include the following elements.

A substrate processing apparatus according to the present invention may include: a chamber; a substrate supporting unit disposed in the chamber; an injection unit disposed above the substrate supporting unit; a first source supply unit for supplying a first source gas; a second source supply unit for supplying a second source gas; a first supply line connecting the first source supply unit with the injection unit; a second supply line connecting the second source supply unit with the injection unit; a mixing unit installed in the first supply line so as to be disposed between the first source supply unit and the injection unit; a first connection line connecting the second supply line with at least one of the first supply line and the mixing unit; and a first path change unit installed at a first connection point at which the first connection line is connected with the second supply line. The first path change unit may change a flow path of the second source gas so that the second source gas supplied from the second source supply unit is supplied to one selected from among the mixing unit and the injection unit.

A method of manufacturing metal oxide semiconductor according to the present invention forms an oxide layer on an exposed surface of a thin film and may include: a) step of preparing a substrate where the exposed surface of the thin film is patterned; b) step of forming a first channel layer on the exposed surface by using at least one of indium oxide (InO), zinc oxide (ZnO), and tin oxide (SnO); and c) step of forming a second channel layer by using gallium oxide (GaO).

According to the present invention, the following effects may be realized.

A substrate processing apparatus according to the present invention is implemented to generate a mixed gas by mixing a plurality of source gases in a mixing space which is relatively wider than an inner portion of an injection unit. Accordingly, the substrate processing apparatus according to the present invention may enhance the easiness of an operation of controlling a mixing composition ratio of a plurality of source gases. Also, the substrate processing apparatus according to the present invention may decrease a deviation of a mixing composition ratio of a plurality of source gases, thereby enhancing the film quality of a thin film which is formed by using a plurality of source gases.

The substrate processing apparatus according to the present invention is implemented to perform all of a co-flow processing process of injecting a mixed gas, where a plurality of source gases are mixed with one another, toward a substrate and a nano-lamination processing process of sequentially injecting a plurality of source gases toward a substrate. Accordingly, the substrate processing apparatus according to the present invention may provide a customer with an option of a processing process, and thus, may contribute to enable the customer to secure the diversity of a processing process capable of being performed and moreover may contribute to reduce the equipment construction cost of the customer.

The substrate processing apparatus according to the present invention is implemented so that a portion of a source gas is directly transferred to an injection unit without passing through a mixing unit, in a case where a processing process is performed based on a nano-lamination process of sequentially injecting a plurality of source gases toward a substrate. Accordingly, the substrate processing apparatus according to the present invention may omit a purge process of purging an inner portion of the mixing unit by using a purge gas, in a case which performs a nano-lamination processing process, and thus, may reduce a time taken in a processing process to increase the productivity of a substrate on which a processing process has been performed.

A method of manufacturing metal oxide semiconductor according to the present invention may be implemented to first form a first channel layer by using at least one of indium, zinc, and tin, which have higher reactivity on a hydroxyl radical (—OH) of a thin film than that of gallium. Accordingly, the method of manufacturing metal oxide semiconductor according to the present invention may enhance a step coverage to enhance the film quality of an oxide layer.

The method of manufacturing metal oxide semiconductor according to the present invention may be implemented to independently form a first channel layer and a second channel layer. Accordingly, the method of manufacturing metal oxide semiconductor according to the present invention may enhance the accuracy and easiness of an operation of controlling a composition ratio between a precursor of the first channel layer and a precursor of the second channel layer.

### BRIEF DESCRIPTION OF DRAWINGS

FIG. 1 is a schematic block diagram of a substrate processing apparatus according to the related art.

FIG. 2 is a schematic block diagram of a substrate processing apparatus according to the present invention.

FIGS. 3 and 4 are schematic side cross-sectional views of an injection unit injecting a gas in a substrate processing apparatus according to the present invention.

FIGS. 5, 6, 7, and 8 are schematic block diagrams of a substrate processing apparatus according to the present invention.

FIG. 9 is a schematic side cross-sectional view illustrating an example of a metal oxide semiconductor.

FIGS. 10, 11, and 12 are schematic flowcharts of a method of manufacturing metal oxide semiconductor according to the present invention.

FIGS. 13 and 14 are schematic flowcharts of a method of manufacturing metal oxide semiconductor according to a modified embodiment of the present invention.

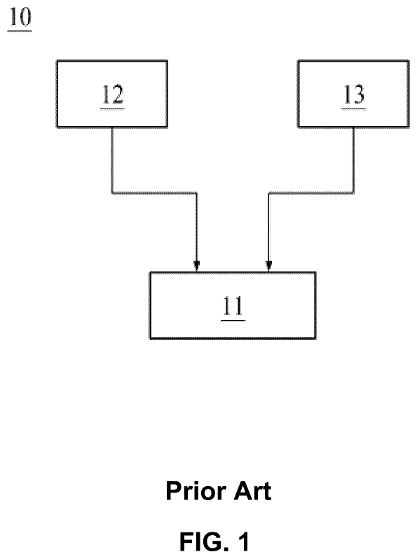

### DETAILED DESCRIPTION OF EXEMPLARY EMBODIMENTS

Hereinafter, an embodiment of a substrate processing apparatus according to the present invention will be described in detail with reference to the accompanying drawings.

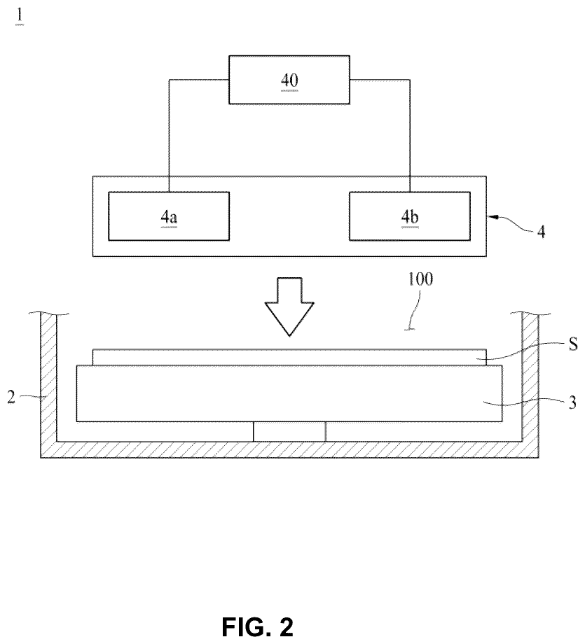

Referring to FIG. 2, a substrate processing apparatus 1 according to the present invention performs a processing process on a substrate S. The substrate S may be a silicon substrate, a glass substrate, a metal substrate, or the like. The substrate processing apparatus 1 according to the present invention may perform a deposition process of depositing a thin film on the substrate S, an etching process of removing a portion of the thin film deposited on the substrate S, etc. Hereinafter, an embodiment where the substrate processing apparatus 1 according to the present invention performs the deposition process will be described mainly, and based thereon, it is obvious to those skilled in the art that an embodiment is devised where the substrate processing apparatus 1 according to the present invention performs another processing process such as the etching process.

The substrate processing apparatus 1 according to the present invention may include a chamber 2, a substrate supporting unit 3, and an injection unit 4.

Referring to FIG. 2, the chamber 2 provides a processing space 100. A processing process such as a deposition process and an etching process on the substrate S may be performed in the processing space 100. The processing space 100 may be disposed in the chamber 2. An exhaust port (not shown) which exhausts a gas from the processing space 100 may be coupled to the chamber 2. The substrate supporting unit 3 and the injection unit 4 may be disposed in the chamber 2.

Referring to FIG. 2, the substrate supporting unit 3 supports the substrate S. The substrate supporting unit 3 may support the one substrate S, or may support a plurality of substrates S. When the plurality of substrates S are supported by the substrate supporting unit 3, a processing process on the plurality of substrates S may be performed at a time. The substrate supporting unit 3 may be coupled to the chamber 2. The substrate supporting unit 3 may be disposed in the chamber 2.

Referring to FIGS. 2 to 4, the injection unit 4 injects a gas toward the substrate supporting unit 3. The injection unit 4 may be disposed in the chamber 2. The injection unit 4 may be disposed to be opposite to the substrate supporting unit 3. The injection unit 4 may be disposed above the substrate supporting unit 3 with respect to a vertical direction. The vertical direction is an axial direction parallel to a direction in which the injection unit 4 and the substrate supporting unit 3 are apart from each other. The processing space 100 may be disposed between the injection unit 4 and the substrate supporting unit 3. The injection unit 4 may be coupled to a lid (not shown). The lid may be coupled to the chamber 2 to cover an upper portion of the chamber 2. The injection unit 4 may be connected with a gas supply unit 40. In this case, the injection unit 4 may inject a gas, supplied from the gas supply unit 40, toward the substrate supporting unit 3.

The injection unit 4 may include a first gas flow path 4a and a second gas flow path 4b.

The first gas flow path 4a is for injecting a gas. The first gas flow path 4a may communicate with the processing space 100. Therefore, a gas may flow along the first gas flow path 4a, and then, may be injected into the processing space 100 through the first gas flow path 4a. The first gas flow path 4a may function as a flow path for enabling a gas to flow and may function as an injection port for injecting a gas into the processing space 100. One side of the first gas flow path 4a may be connected with the gas supply unit 40 through a pipe, a hose, or a gas block. The other side of the first gas flow path 4a may communicate with the processing space 100. Accordingly, a gas supplied from the gas supply unit 40 may flow along the first gas flow path 4a, and then, may be injected into the processing space 100 through the first gas flow path 4a.

The second gas flow path 4b is for injecting a gas. A gas injected through the second gas flow path 4b and a gas injected through the first gas flow path 4a may be different gases. For example, the gas injected through the second gas flow path 4b and the gas injected through the first gas flow path 4a may be different source gases. For example, the gas injected through the second gas flow path 4b may be a reactant gas, and the gas injected through the first gas flow path 4a may be a source gas. The second gas flow path 4b may communicate with the processing space 100. Therefore, a gas may flow along the second gas flow path 4b, and then, may be injected into the processing space 100 through the second gas flow path 4b. The second gas flow path 4b may function as a flow path for enabling a gas to flow and may function as an injection port for injecting a gas into the processing space 100. One side of the second gas flow path 4b may be connected with the gas supply unit 40 through a pipe, a hose, or a gas block. The other side of the second gas flow path 4b may communicate with the processing space 100. Accordingly, a gas supplied from the gas supply unit 40 may flow along the second gas flow path 4b, and then, may be injected into the processing space 100 through the second gas flow path 4b.

The second gas flow path 4b and the first gas flow path 4a may be disposed to be spatially separated from each other. Therefore, the injection unit 4 may be implemented so that a gas flowing along the second gas flow path 4b and a gas flowing along the first gas flow path 4a are not mixed with each other until before being injected into the processing space 100. The second gas flow path 4b and the first gas flow path 4a may inject a gas toward different portions of the processing space 100.

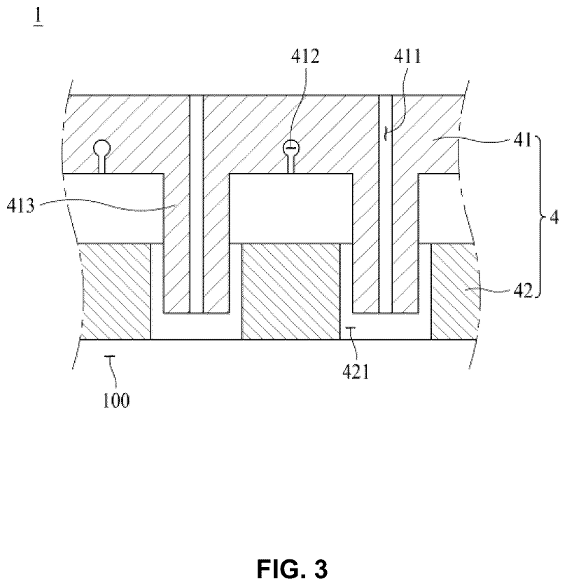

As illustrated in FIG. 3, the injection unit 4 may include a first plate 41 and a second plate 42.

The first plate 41 is disposed above the second plate 42. The first plate 41 and the second plate 42 may be disposed apart from each other. A plurality of first gas holes 411 may be formed in the first plate 41. Each of the first gas holes 411 may function as a path for enabling a gas to flow. The first gas holes 411 may be included in the first gas flow path 4a. A plurality of second gas holes 412 may be formed in the first plate 41. Each of the second gas holes 412 may function as a path for enabling a gas to flow. The second gas holes 412 may be included in the second gas flow path 4b. A plurality of protrusion members 413 may be formed in the first plate 41. The protrusion members 413 may protrude toward the second plate 42 from a lower surface of the first plate 41. Each of the first gas holes 411 may be formed to pass through the first plate 41 and the protrusion member 413.

A plurality of openings 421 may be formed in the second plate 42. The openings 421 may be formed to pass through the second plate 42. The openings 421 may be disposed at a position corresponding to each of the protrusion members 413. Therefore, as illustrated in FIG. 3, the protrusion members 413 may be formed by a length which enables the protrusion members 413 to be respectively inserted into the openings 421. Although not shown, the protrusion members 413 may be formed by a length which enables the protrusion members 413 to be respectively disposed above the openings 421. The protrusion members 413 may be formed by a length which protrudes downward from the second plate 42. The second gas holes 412 may be disposed to inject a gas toward an upper surface of the second plate 42. Although not shown, the protrusion member 413 may not be provided in the second plate 42. In this case, a lower surface of the second plate 42 facing the first plate 41 may be formed to be flat.

The injection unit 4 may generate plasma by using the second plate 42 and the first plate 41. In this case, a plasma power such as radio frequency (RF) power may be applied to the first plate 41, and the second plate 42 may be grounded. The first plate 41 may be grounded, and the plasma power may be applied to the second plate 42.

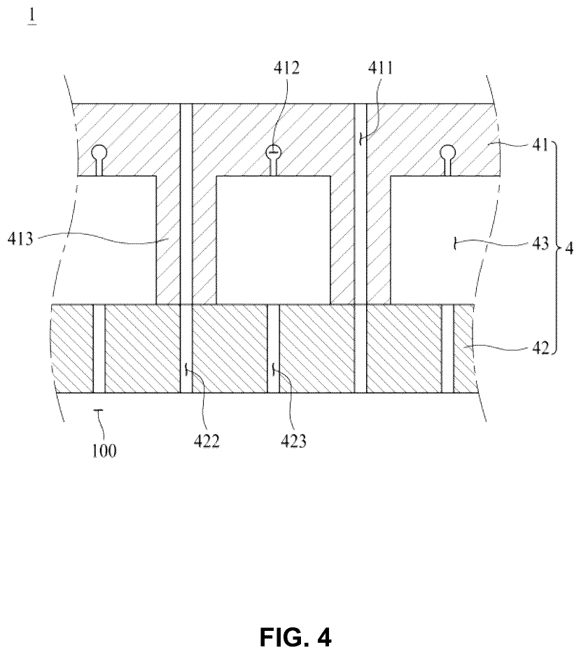

As illustrated in FIG. 4, a plurality of first openings 422 and a plurality of second openings 423 may be formed in the second plate 42.

The first openings 422 may be formed to pass through the second plate 42. The first openings 422 may be respectively connected with the first gas holes 411. In this case, the protrusion members 413 may be disposed to contact an upper surface of the second plate 42. A gas may be injected into the processing space 100 via the first gas holes 411 and the first openings 422. The first gas holes 411 and the first openings 422 may be included in the first gas flow path 4a.

The second openings 423 may be formed to pass through the second plate 42. The second openings 423 may be respectively connected with a buffer space 43 which is disposed between the first plate 41 and the second plate 42. A gas may be injected into the processing space 100 via the second gas holes 412, the buffer space 43, and the second openings 423. The second gas holes 412, the buffer space 43, and the second openings 423 may be included in the second gas flow path 4b.

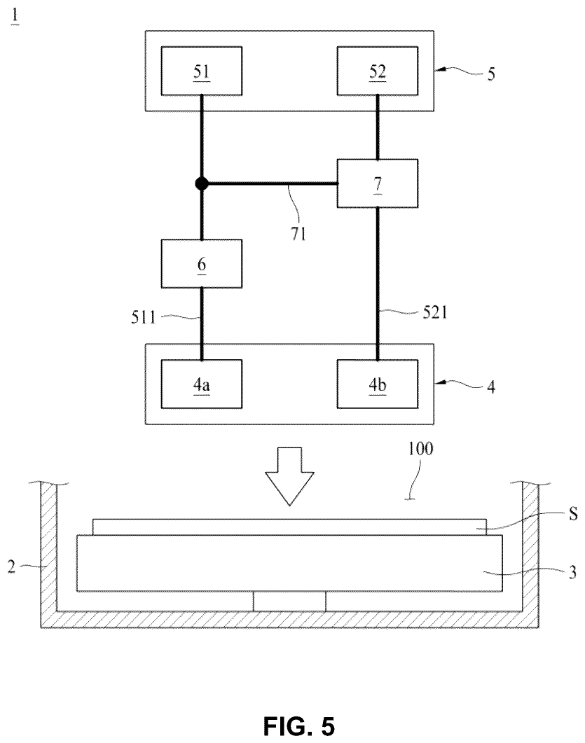

Referring to FIG. 5, the substrate processing apparatus 1 according to the present invention may further include a source supply unit 5.

The source supply unit 5 is for supplying a source gas. The source supply unit 5 may be included in the gas supply unit 40. The source supply unit 5 may supply the source gas to the injection unit 4. In this case, the injection unit 4 may inject the source gas, supplied from the source supply unit 5, toward the substrate supporting unit 3. The source supply unit 5 may include a storage tank (not shown) for storing the source gas and a flow rate control valve (not shown) for controlling the amount of source gas discharged from the storage tank and supplied to the injection unit 4.

The source supply unit 5 may include a first source supply unit 51 and a second source supply unit 52.

The first source supply unit 51 is for supplying a first source gas. The first source supply unit 51 may be connected with the injection unit 4 through a first supply line 511. When the injection unit 4 includes the first gas flow path 4a and the second gas flow path 4b, the first supply line 511 may be connected with each of the first source supply unit 51 and the first gas flow path 4a. The first supply line 511 may be implemented as a hose, a pipe, a tube, or the like. The first supply line 511 may be implemented as a hole which is formed in a certain structure.

The second source supply unit 52 is for supplying a second source gas. The second source supply unit 52 may be connected with the injection unit 4 through a second supply line 521. When the injection unit 4 includes the first gas flow path 4a and the second gas flow path 4b, the second supply line 521 may be connected with each of the second source supply unit 52 and the second gas flow path 4b. The second supply line 521 may be implemented as a hose, a pipe, a tube, or the like. The second supply line 521 may be implemented as a hole which is formed in a certain structure. Each of the second source gas and the first source gas may include at least one of indium, gallium, zinc, and oxide. The second source gas and the first source gas may be different gases.

Referring to FIG. 5, the substrate processing apparatus 1 according to the present invention may include a mixing unit 6.

The mixing unit 6 is installed in the first supply line 511. The mixing unit 6 may be disposed between the first source supply unit 51 and the injection unit 4. The mixing unit 6 may mix a plurality of source gases to generate a mixed gas. In a case where the substrate processing apparatus 1 according to the present invention performs a processing process by using a co-flow process of injecting a mixed gas where a plurality of source gases are mixed with one another, the mixing unit 6 may mix the first source gas, supplied from the first source supply unit 51, with the second source gas supplied from the second source supply unit 52 to generate a mixed gas, and then, may transfer the mixed gas to the injection unit 4 through the first supply line 511. In this case, the mixed gas may be supplied to the first gas flow path 4a through the first supply line 511 from the mixing unit 6 and may be injected toward the substrate S through the first gas flow path 4a. Furthermore, the second source gas may not be supplied to the second gas flow path 4b.

As described above, the substrate processing apparatus 1 according to the present invention is implemented to generate a mixed gas by mixing a plurality of source gases through the mixing unit 6 provided independently from the injection unit 4. Therefore, comparing with a comparative example which mixes a plurality of source gases to generate a mixed gas in the injection unit 4, the substrate processing apparatus 1 according to the present invention may mix a plurality of source gases to generate a mixed gas in the mixing unit 6 which is wider than an inner portion of the injection unit 4. Accordingly, the substrate processing apparatus 1 according to the present invention may enhance the easiness of an operation of controlling a mixing composition ratio of a plurality of source gases. Also, the substrate processing apparatus 1 according to the present invention may decrease a deviation of a mixing composition ratio of a plurality of source gases, thereby enhancing the film quality of a thin film which is formed by using a plurality of source gases.

The mixing unit 6 may be disposed outside the chamber 2. The mixing unit 6 may be disposed apart from the lid of the chamber 2. The mixing unit 6 may be coupled to the lid of the chamber 2. The mixing unit 6 may be implemented as a tank where a mixing space is provided therein.

Referring to FIGS. 5 to 7, the substrate processing apparatus 1 according to the present invention may include a first path change unit 7.

The first path change unit 7 changes a flow path of the second source gas. The first path change unit 7 may change the flow path of the second source gas so that the second source gas supplied from the second source supply unit 52 is supplied to one element selected from among the mixing unit 6 and the injection unit 4.

When the first path change unit 7 changes the flow path of the second source gas so that the second source gas is supplied to the mixing unit 6, the second source gas may be supplied to the injection unit 4 via the mixing unit 6. Accordingly, the injection unit 4 may inject a mixed gas, where the first source gas and the second source gas are mixed with each other, toward the substrate S. In this case, the substrate processing apparatus 1 according to the present invention may perform the co-flow processing process, and thus, may deposit a thin film layer, formed of the mixed gas, on the substrate S.

When the first path change unit 7 changes the flow path of the second source gas so that the second source gas is supplied to the injection unit 4, the second source gas may be supplied to the injection unit 4 without passing through the mixing unit 6. Accordingly, the injection unit 4 may individually inject the first source gas and the second source gas toward the substrate S in a state where the first source gas is not mixed with the second source gas. In this case, the substrate processing apparatus 1 according to the present invention may perform the nano-lamination processing process, and thus, may sequentially deposit a thin film layer formed of the first source gas and a thin film layer formed of the second source gas, on the substrate S.

As described above, the substrate processing apparatus 1 according to the present invention is implemented to perform all of the co-flow processing process and the nano-lamination processing process by using the first path change unit 7. Accordingly, the substrate processing apparatus 1 according to the present invention may provide a customer with an option of a processing process, and thus, may contribute to enable the customer to secure the diversity of a processing process capable of being performed and moreover may contribute to reduce the equipment construction cost of the customer. In this case, a selection for selecting one element, to which the second source gas is to be supplied, from among the mixing unit 6 and the injection unit 4 may be performed by a worker. The selection for selecting one element, to which the second source gas is to be supplied, from among the mixing unit 6 and the injection unit 4 may be performed based on a predetermined process sequence.

Moreover, the substrate processing apparatus 1 according to the present invention is implemented so that the second source gas is transferred to the injection unit 4 without passing through the mixing unit 6, in a case which performs a processing process based on the nano-lamination process, and thus, is implemented so that the second source gas is not supplied to the mixing unit 6. Accordingly, the substrate processing apparatus 1 according to the present invention may omit a purge process of purging an inner portion of the mixing unit 6 by using a purge gas, in a case which performs a processing process based on the nano-lamination process, and thus, may reduce a time taken in a processing process to increase the productivity of a substrate S on which a processing process has been performed. This will be described below in detail.

First, in a comparative example where all of the first source gas and the second source gas pass through the mixing unit 6 in performing a processing process based on the nano-lamination process, when the first source gas is transferred to the injection unit 4 via the mixing unit 6, a first source gas remaining in the mixing unit 6 occurs. Therefore, the comparative example should supply the second source gas to the mixing unit 6 after performing a purge process on the mixing unit 6, so as to prevent the first source gas and the second source gas from being mixed with each other. Accordingly, in the comparative example, a time for performing a processing process by using the first source gas and the second source gas may be inevitably delayed by a time taken in performing a purge process on the mixing unit 6.

On the other hand, the substrate processing apparatus 1 according to the present invention is implemented so that the second source gas is transferred to the injection unit 4 without passing through the mixing unit 6, in a case which performs a processing process based on the nano-lamination process, and thus, is implemented so that a purge process on the mixing unit 6 is not needed. Accordingly, comparing with the comparative example, the substrate processing apparatus 1 according to the present invention may shorten a time, taken in a processing process, by a time taken in performing a purge process on the mixing unit 6. Also, it is possible to omit facilities for performing the purge process on the mixing unit 6, and thus, the substrate processing apparatus 1 according to the present invention may contribute to reduce the construction cost and the process cost.

The first path change unit 7 may be installed at a first connection point 71a at which a first connection line 71 is connected with the second supply line 521. The first connection line 71 connects the second supply line 521 to at least one of the first supply line 511 and the mixing unit 6.

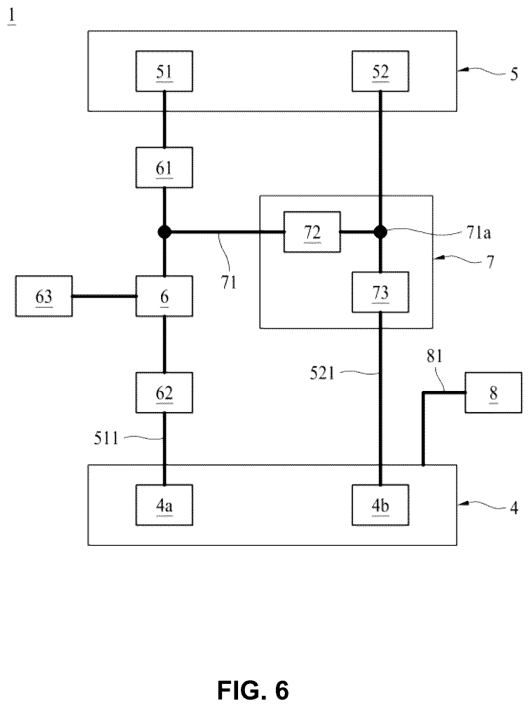

As illustrated in FIG. 6, one side of the first connection line 71 may be connected with the second supply line 521 at the first connection point 71a, and the other side of the first connection line 71 may be connected with the first supply line 511, between the first source supply unit 51 and the mixing unit 6. In this case, in a case which performs a processing process based on the co-flow process, a flow path of the second source gas may be changed by the first path change unit 7, and thus, the second source gas may flow along the second supply line 521, the first connection line 71, and the first supply line 511 and may be supplied to the mixing unit 6.

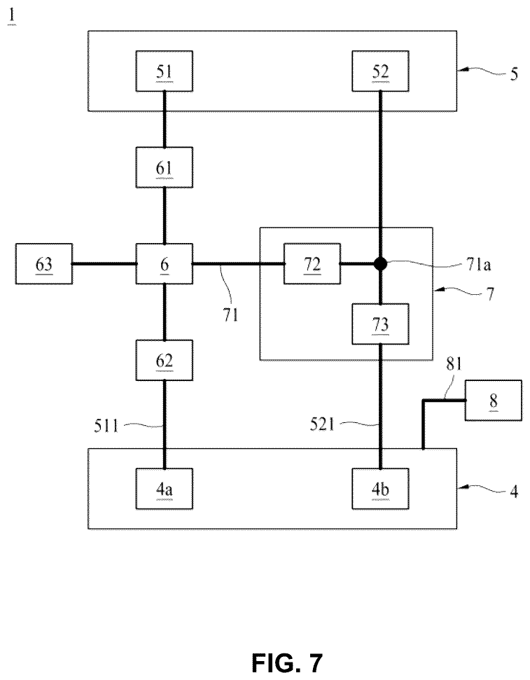

As illustrated in FIG. 7, one side of the first connection line 71 may be connected with the second supply line 521 at the first connection point 71a, and the other side of the first connection line 71 may be connected with the mixing unit 6. In this case, in a case which performs a processing process based on the co-flow process, a flow path of the second source gas may be changed by the first path change unit 7, and thus, the second source gas may flow along the first connection line 71 and may be directly supplied to the mixing unit 6.

Although not shown, one side of the first connection line 71 may be connected with the second supply line 521 at the first connection point 71a, and the other side of the first connection line 71 may branch and may be connected with all of the first supply line 511 and the mixing unit 6. The first connection line 71 may be implemented as a hose, a pipe, a tube, or the like. The first connection line 71 may be implemented as a hole which is formed in a certain structure.

The first path change unit 7 may include a first connection valve 72 and a first supply valve 73.

The first connection valve 72 selectively opens or closes the first connection line 71. The first connection valve 72 may be installed in the first connection line 71, between one side of the first connection line 71 and the other side of the first connection line 71.

The first supply valve 73 selectively opens or closes the second supply line 521. The first supply valve 73 may be installed in the second supply line 521, between the first connection point 71a and the injection unit 4.

The first path change unit 7 may change a flow path of the second source gas by using the first connection valve 72 and the first supply valve 73.

For example, in a case where the injection unit 4 injects a mixed gas, where a plurality of source gases are mixed with one another, toward the substrate S to perform a processing process, the first path change unit 7 may control the first supply valve 73 to close the second supply line 521 and may control the first connection valve 72 to open the first connection line 71. Accordingly, the first path change unit 7 may change the flow path of the second source gas so that the second source gas is supplied to the mixing unit 6.

For example, in a case where the injection unit 4 sequentially injects a plurality of source gases toward the substrate S to perform a processing process, the first path change unit 7 may control the first connection valve 72 to close the first connection line 71 and may control the first supply valve 73 to open the second supply line 521. Accordingly, the first path change unit 7 may change the flow path of the second source gas so that the second source gas is supplied to the injection unit 4. In this case, the first path change unit 7 may control the first supply valve 73 to open or close the second supply line 521 in a process sequence of a processing process while maintaining a state where the first path change unit 7 controls the first connection valve 72 to close the first connection line 71. For example, the first path change unit 7 may control the first supply valve 73 so that the second supply line 521 is opened, in only a period, where the second source gas is injected toward the substrate S, of the process sequence. The first path change unit 7 may control the first supply valve 73 so that the second supply line 521 is closed, in the other period, except the period where the second source gas is injected toward the substrate S, of the process sequence.

Here, a first mixing valve 61 and a second mixing valve 62 may be installed in the first supply line 511.

The first mixing valve 61 is disposed between the first source supply unit 51 and the mixing unit 6. That is, the first mixing valve 61 may be disposed at an inlet side of the mixing unit 6. The first mixing valve 61 may open or close the first supply line 511 at the inlet side of the mixing unit 6, and thus, may change the supply or not of the first source gas to the mixing unit 6.

The second mixing valve 62 is disposed between the mixing unit 6 and the injection unit 4. That is, the second mixing valve 62 may be disposed at an outlet side of the mixing unit 6. The second mixing valve 62 may open or close the first supply line 511 at the outlet side of the mixing unit 6, and thus, may change the supply or not of the first source gas or a mixed gas, where the first source gas is mixed with the second source gas, to the injection unit 4.

In a case where the substrate processing apparatus 1 according to the present invention performs a processing process based on the co-flow process, the first mixing valve 61 and the second mixing valve 62 may operate as follows.

First, until the supply of the first source gas and the second source gas to the mixing unit 6 is completed, the first mixing valve 61 opens the first supply line 511 and the second mixing valve 62 closes the first supply line 511. In this case, the first supply valve 73 closes the second supply line 521, and the first connection valve 72 opens the first connection line 71. Accordingly, the first source gas and the second source gas may be supplied to the mixing unit 6.

Subsequently, when the supply of the first source gas and the second source gas to the mixing unit 6 is completed, the first mixing valve 61 opens the first supply line 511 and the first connection valve 72 closes the first connection line 71. In this case, the second mixing valve 62 maintains the first supply line 511 in a closed state, and the first supply valve 73 maintains the second supply line 521 in a closed state. In this state, a process of mixing the first source gas with the second source gas to generate the mixed gas may be performed in the mixing unit 6.

Subsequently, when the first source gas and the second source gas are mixed with each other to generate the mixed gas, the second mixing valve 62 opens the first supply line 511. In this case, when the first mixing valve 61 maintains the first supply line 511 in a closed state and the first connection valve 72 maintains the first connection line 71 in a closed state, the first supply valve 73 maintains the second supply line 521 in a closed state. The mixed gas may flow along the first supply line 511 and may be supplied to the injection unit 4.

As described above, the substrate processing apparatus 1 according to the present invention may enhance a mixing ratio of a plurality of source gases by using the first mixing valve 61 and the second mixing valve 62. Accordingly, the substrate processing apparatus 1 according to the present invention may more enhance the easiness of an operation of controlling a mixing composition ratio of a plurality of source gases and may more decrease a deviation of a mixing composition ratio of a plurality of source gases, thereby more enhancing the film quality of a thin film which is formed by using a plurality of source gases. Also, the substrate processing apparatus 1 according to the present invention may increase a pressure of an internal mixed gas of the mixing unit 6 by using the first mixing valve 61 and the second mixing valve 62. Therefore, the substrate processing apparatus 1 according to the present invention may inject the mixed gas toward the substrate S through the injection unit 4 with a stronger injection pressure, and thus, may more enhance the quality of a substrate on which a processing process has been performed.

Here, based on a selection by a customer, the substrate processing apparatus 1 according to the present invention may operate to perform only a processing process based on the co-flow process, or may operate to perform only a processing process based on the nano-lamination process. Furthermore, based on a selection by a customer, the substrate processing apparatus 1 according to the present invention may operate to sequentially perform a processing process based on the co-flow process and a processing process based on the nano-lamination process. In this case, the injection unit 4 may inject a mixed gas, where a plurality of source gases are mixed with one another, toward the substrate S to perform a first processing process, and then, may sequentially inject a plurality of source gases toward the substrate S to perform a second processing process. That is, the injection unit 4 may sequentially inject the mixed gas, the first source gas, and the second source gas toward the substrate S. As described above, in a case where all of the first processing process and the second processing process are performed, the substrate processing apparatus 1 according to the present invention may further include an inter-purge unit 63.

The inter-purge unit 63 is connected with the mixing unit 6. To perform the second processing process after the first processing process is performed, before only the first source gas is supplied to the mixing unit 6, a purge gas which purges an inner portion of the mixing unit 6 may be supplied to the mixing unit 6. Accordingly, the inter-purge unit 63 may remove a mixed gas, remaining in the mixing unit 6, from the mixing unit 6. Subsequently, the first source gas may be supplied to the mixing unit 6. Therefore, the substrate processing apparatus 1 according to the present invention may prevent the mixed gas from being injected in a state where the mixed gas is mixed with the first source gas, in performing the second processing process after the first processing process is performed. Accordingly, the substrate processing apparatus 1 according to the present invention is implemented to enhance the quality of a thin film formed on the substrate S even when a processing process based on the co-flow process and a processing process based on the nano-lamination process are sequentially performed.

Referring to FIGS. 5 to 7, the substrate processing apparatus 1 according to the present invention may include a reactant supply unit 8.

The reactant supply unit 8 is for supplying a reactant gas to the injection unit 4. The reactant supply unit 8 may be included in the gas supply unit 40. The reactant supply unit 8 may supply a reactant gas capable of reacting with at least one of source gases supplied by the source supply unit 5. The injection unit 4 may inject the reactant gas, supplied from the reactant supply unit 8, toward the substrate supporting unit 3. The reactant supply unit 8 may include a storage tank (not shown) for storing a reactant gas and a flow rate control valve (not shown) for controlling the amount of reactant gas discharged from the storage tank and supplied to the injection unit 4. The reactant supply unit 8 may be connected with at least one of the first gas flow path 4a and the second gas flow path 4b. The reactant supply unit 8 may be connected with a third gas flow path (not shown) included in the injection unit 4. The reactant supply unit 8 may be connected with the injection unit 4 through a supply line 81. The supply line 81 may be implemented as a hose, a pipe, a tube, or the like. The supply line 81 may be implemented as a hole which is formed in a certain structure.

Although not shown, the substrate processing apparatus 1 according to the present invention may include a purge supply unit. The purge supply unit is for supplying a purge gas to the injection unit 4. The purge supply unit may be included in the gas supply unit 40. The injection unit 4 may inject the purge gas, supplied from the purge supply unit, toward the substrate supporting unit 3. The purge supply unit may be connected with at least one of the first gas flow path 4a and the second gas flow path 4b. The purge supply unit may be connected with a purge gas flow path (not shown) included in the injection unit 4. The purge supply unit may be connected with at least one of the first supply line 511 and the second supply line 521. The purge supply unit may be connected with the injection unit 4 through a separate supply line.

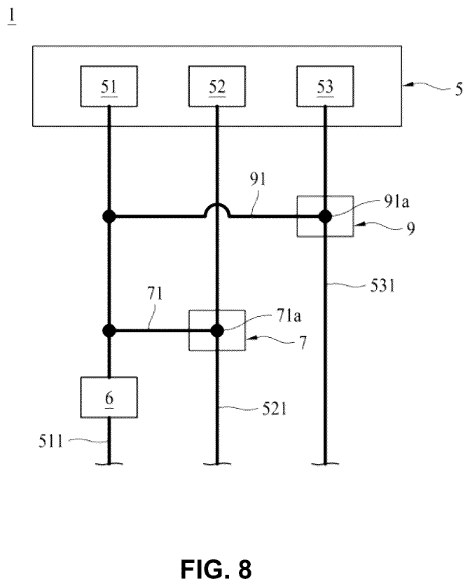

Referring to FIGS. 5 to 8, the substrate processing apparatus 1 according to the present invention may be implemented to perform a processing process by using three or more source gases. For example, in a case where the substrate processing apparatus 1 according to the present invention performs a processing process by using three source gases, the source supply unit 5 may further include a third source supply unit 53 (illustrated in FIG. 8).

The third source supply unit 53 is for supplying a third source gas. The third source supply unit 53 may be connected with the injection unit 4 through the third supply line 531. In this case, the injection unit 4 may include a third gas flow path (not shown) for injecting the third source gas. The third source supply unit 53 may be connected with at least one of the first gas flow path 4a and the second gas flow path 4b through a third supply line 531. The third supply line 531 may be implemented as a hose, a pipe, a tube, or the like. The third supply line 531 may be implemented as a hole which is formed in a certain structure.

Moreover, the substrate processing apparatus 1 according to the present invention may further include a second path change unit 9 (illustrated in FIG. 8).

The second path change unit 9 changes a flow path of the third source gas. The second path change unit 9 may change the flow path of the third source gas so that the third source gas supplied from the third source supply unit 53 is supplied to at least one element selected from among the mixing unit 6 and the injection unit 4.

When the second path change unit 9 changes the flow path of the third source gas so that the third source gas is supplied to the mixing unit 6, the third source gas may be supplied to the injection unit 4 via the mixing unit 6. Accordingly, the injection unit 4 may inject a mixed gas, where the third source gas is additionally mixed with at least one of the first source gas and the second source gas, toward the substrate S. In this case, the substrate processing apparatus 1 according to the present invention may perform a processing process based on the nano-lamination process, and thus, may deposit a thin film layer, formed of the mixed gas, on the substrate S.

When the second path change unit 9 changes the flow path of the third source gas so that the third source gas is supplied to the injection unit 4, the third source gas may be supplied to the injection unit 4 without passing through the mixing unit 6. Accordingly, the injection unit 4 may individually inject the first source gas, the second source gas, and the third source gas toward the substrate S in a state where the first to third source gases are not mixed with one another. In this case, the substrate processing apparatus 1 according to the present invention may perform a processing process based on the nano-lamination process, and thus, may sequentially deposit a thin film layer formed of the first source gas, a thin film layer formed of the second source gas, and a thin film layer formed of the third source gas, on the substrate S.

The second path change unit 9 may be installed at a second connection point 91a at which a second connection line 91 is connected with the third supply line 531. The second connection line 91 connects the third supply line 531 to at least one of the first supply line 511 and the mixing unit 6.

As illustrated in FIG. 8, one side of the second connection line 91 may be connected with the third supply line 531 at the second connection point 91a, and the other side of the second connection line 91 may be connected with the first supply line 511, between the first source supply unit 51 and the mixing unit 6. In this case, in a case which performs a processing process based on the co-flow process, a flow path of the third source gas may be changed by the second path change unit 9, and thus, the third source gas may flow along the third supply line 531, the second connection line 91, and the first supply line 511 and may be supplied to the mixing unit 6.

Although not shown, one side of the second connection line 91 may be connected with the third supply line 531 at the second connection point 91a, and the other side of the second connection line 91 may be directly connected with the mixing unit 6. In this case, in a case which performs a processing process based on the co-flow process, a flow path of the third source gas may be changed by the second path change unit 9, and thus, the third source gas may flow along the third supply line 531 and the second connection line 91 and may be directly supplied to the mixing unit 6.

Although not shown, one side of the second connection line 91 may be connected with the third supply line 531 at the second connection point 91a, and the other side of the second connection line 91 may branch and may be connected with all of the first supply line 511 and the mixing unit 6. The second connection line 91 may be implemented as a hose, a pipe, a tube, or the like. The second connection line 91 may be implemented as a hole which is formed in a certain structure.

Although not shown, the second path change unit 9 may include a second connection valve which selectively opens or closes the second connection line 91 and a second supply valve which selectively opens or closes the third supply line 531. The second connection valve and the second supply valve have only a disposition difference with each of the first connection valve 72 and the first supply valve 73, and thus, detailed descriptions thereof are omitted.

Furthermore, in a case where the substrate processing apparatus 1 according to the present invention performs a processing process by using N (where N is an integer of more than 3) number of source gases, the substrate processing apparatus 1 according to the present invention may be implemented to include N number of source supply units, N number of supply lines, N number of path change units, and N number of connection lines.

Hereinafter, an embodiment of a method of manufacturing metal oxide semiconductor according to the present invention will be described in detail with reference to the accompanying drawings. In describing an embodiment of the present invention, in a case where an arbitrary structure is described as being formed in another structure, such description should be construed as including a case, where a third structure is disposed between the structures, as well as a case where the structures contact each other.

Referring to FIGS. 2 to 9, a method of manufacturing metal oxide semiconductor according to the present invention is for manufacturing a metal oxide semiconductor 200 on a substrate S by forming an oxide layer 230. The substrate S may be a silicon substrate, a glass substrate, a metal substrate, or the like. The method of manufacturing metal oxide semiconductor according to the present invention may be performed by the substrate processing apparatus 1 according to the present invention described above.

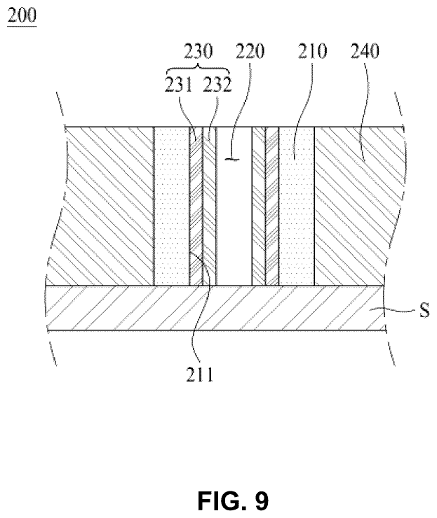

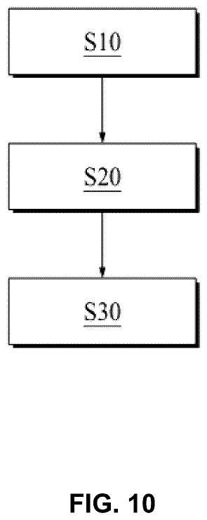

Referring to FIGS. 2 to 10, the method of manufacturing metal oxide semiconductor according to the present invention may manufacture a metal oxide semiconductor 200 which includes a thin film 210 formed on the substrate S as illustrated in FIG. 9 and the oxide layer 230 formed on an exposed surface 211 of the thin film 210. The exposed surface 211 is a surface of the thin film 210 exposed by patterning of the thin film 210. In FIG. 9, it is illustrated that the exposed surface 211 corresponds to a side surface of the thin film 210, but the present invention is not limited thereto and the exposed surface 211 may correspond to another surface included in the thin film 210. The exposed surface 211 may be exposed by a through hole 220 formed in the thin film 210. When the metal oxide semiconductor 200 is a three-dimensional transistor, the thin film 210 may be a gate insulation layer. In this case, the exposed surface 211 may correspond to a side surface of the gate insulation layer. A thin film layer 240 may be disposed at both sides of the thin film 210. When the metal oxide semiconductor 200 is a three-dimensional transistor, the thin film layer 240 may be implemented in a structure where a plurality of oxide films and a plurality of word lines WL are alternately stacked. The thin film layer 240 may be formed on the substrate S and a pattern hole may be formed in the thin film layer 240 through an etching process, and then, the thin film 210 may be formed on a side surface of the thin film layer 240 exposed by the pattern hole. The oxide layer 230 may be implemented as an IGZO oxide layer including indium (In), gallium (Ga), zinc (Zn), and oxide (O). The oxide layer 230 may be implemented as an ITGO oxide layer including indium (In), tin (Sn), gallium (Ga), and oxide (O).

The method of manufacturing metal oxide semiconductor according to the present invention may include a) step (S10), b) step (S20), and c) step (S30).

The a) step (S10) may be performed by preparing a substrate S where the exposed surface 211 of the thin film 210 is patterned. The a) step (S10) may be performed by loading the substrate S, where the exposed surface 211 of the thin film 210 is patterned, to the substrate supporting unit 3. The substrate S may be loaded to the substrate supporting unit 3 in a state where the through hole 220 is formed in the thin film 210. In this case, the exposed surface 211 may correspond to the side surface of the thin film 210.

The b) step (S20) may be performed by forming a first channel layer 231 on the exposed surface 211 by using at least one of indium oxide (InO), zinc oxide (ZnO), and tin oxide (SnO). The b) step (S20) may be performed by sequentially performing injection of a source gas including at least one of indium, zinc, and tin and injection of a reactant gas including oxide by using the injection unit 4. Therefore, the first channel layer 231 may be formed on the exposed surface 211 through an atomic layer deposition (ALD) process. The source gas including at least one of indium, zinc, and tin may be injected through the first gas flow path 4a. In this case, the first gas flow path 4a may be connected with the source supply unit 5. The reactant gas including oxide may be injected through the second gas flow path 4b. In this case, the third gas flow path may be connected with the reactant supply unit 8.

The c) step (S30) may be performed by forming a second channel layer 232 by using gallium oxide (GaO). The c) step (S30) may be performed by sequentially performing injection of the source gas including gallium and injection of the reactant gas including oxide by using the injection unit 4. Therefore, the second channel layer 232 may be formed on the first channel layer 231 through an ALD process. The source gas including gallium may be injected through the first gas flow path 4a. In this case, the first gas flow path 4a may be connected with the source supply unit 5. The reactant gas including oxide may be injected through the second gas flow path 4b. In this case, the second gas flow path 4b may be connected with the reactant supply unit 8. The reactant gas including oxide may be injected through the third gas flow path. In this case, the third gas flow path may be connected with the reactant supply unit 8.

As described above, the method of manufacturing metal oxide semiconductor according to the present invention may be implemented to first form the first channel layer 231 on the exposed surface 211 by using at least one of indium, zinc, and tin, and then, form the second channel layer 232 by using gallium later. Accordingly, the method of manufacturing metal oxide semiconductor according to the present invention may realize the following effects.

First, the method of manufacturing metal oxide semiconductor according to the present invention may first form the first channel layer 231 by using at least one of indium, zinc, and tin, which have higher reactivity on a hydroxyl radical (—OH) of the thin film 210 than that of gallium, and thus, may prevent a step coverage from being reduced by a high activation barrier which obstructs an initial self-limiting chemical adsorption process between gallium and the hydroxyl radical (—OH) of the thin film 210. In this case, the method of manufacturing metal oxide semiconductor according to the present invention may decrease an activation barrier between the thin film 210 and the first channel layer 231, and thus, may facilitate the surface core growth of a precursor included in the first channel layer 231. Accordingly, the method of manufacturing metal oxide semiconductor according to the present invention may enhance a step coverage of the first channel layer 231 formed on the exposed surface 211, and moreover, may enhance a step coverage of the second channel layer 232 formed on the first channel layer 231, thereby enhancing the film quality of the oxide layer 230.

Second, the method of manufacturing metal oxide semiconductor according to the present invention may be implemented to independently form the first channel layer 231 and the second channel layer 232, and thus, may enhance the accuracy and easiness of an operation of controlling a composition ratio between a precursor of the first channel layer 231 and a precursor of the second channel layer 232. Accordingly, the method of manufacturing metal oxide semiconductor according to the present invention may enhance response capability to a change in the kind and spec of the metal oxide semiconductor 200 and may enhance versatility capable of being applied in forming the oxide layer 230 of various metal oxide semiconductors 200. Also, surface reactivity may be improved through the control of a composition ratio between the precursor of the first channel layer 231 and the precursor of the second channel layer 232, and thus, the method of manufacturing metal oxide semiconductor according to the present invention may more enhance a step coverage of the oxide layer 230.

Third, the method of manufacturing metal oxide semiconductor according to the present invention may be implemented to form the first channel layer 231 including indium oxide and then form the second channel layer 232 including gallium oxide. Indium of the first channel layer 231 may contribute to enhance the deposition uniformity of gallium of the second channel layer 232, and thus, the method of manufacturing metal oxide semiconductor according to the present invention may more enhance a step coverage of the second channel layer 232, thereby more enhancing the film quality of the oxide layer 230. Accordingly, the method of manufacturing metal oxide semiconductor according to the present invention may manufacture the metal oxide semiconductor 200 where the good electrical and chemical characteristic of the oxide layer 230 per each unit cell is ensured in a micro-fine pattern device having a high aspect ratio.

Furthermore, a material included in the first channel layer 231 and a material included in the second channel layer 232 may be mixed with or reacted on each other, and the oxide layer 230 may be implemented as an IGZO oxide layer or an ITGO oxide layer. When the oxide layer 230 is implemented as the IGZO oxide layer, the b) step (S20) may form the first channel layer 231 by using indium oxide and zinc oxide. When the oxide layer 230 is implemented as the ITGO oxide layer, the b) step (S20) may form the first channel layer 231 by using indium oxide and tin oxide.

Moreover, when the metal oxide semiconductor 200 is a three-dimensional transistor, the b) step (S20) may be performed by forming the first channel layer 231 on a side surface of the gate insulation layer, and the c) step (S30) may be performed by forming the second channel layer 232 on a side surface of the first channel layer 231.

Referring to FIGS. 2 to 10, the method of manufacturing metal oxide semiconductor according to the present invention may include a step of repeatedly performing the c) step (S30) after repeatedly performing the b) step (S20). In this case, the first channel layer 231 may be formed of a plurality of layers on the exposed surface 211 by repeatedly performing the b) step (S20), and then, the second channel layer 232 may be formed of a plurality of layers on the first channel layer 231 by repeatedly performing the c) step (S30). The b) step (S20) may be repeatedly performed by sequentially performing injection of a source gas including at least one of indium, zinc, and tin and injection of a reactant gas including oxide a plurality of times. Therefore, the first channel layer 231 may be formed of a plurality of layers through an ALD process. The c) step (S30) may be repeatedly performed by sequentially performing injection of a source gas including gallium and injection of a reactant gas including oxide a plurality of times. Therefore, the second channel layer 232 may be formed of a plurality of layers through an ALD process. A step of repeatedly performing the c) step after repeatedly performing the b) step may be repeatedly performed until the oxide layer 230 is formed on the exposed surface 211 to have a predetermined thickness.

Referring to FIGS. 2 to 11, the method of manufacturing metal oxide semiconductor according to the present invention may further include d) step (S40). The d) step (S40) may be performed by forming the first channel layer 231 by using at least one of indium oxide, zinc oxide, and tin oxide. The d) step (S40) may be performed by sequentially performing injection of a source gas including at least one of indium, zinc, and tin and injection of a reactant gas including oxide by using the injection unit 4. Therefore, the first channel layer 231 may be formed on the second channel layer 232 through an ALD process. The source gas including at least one of indium, zinc, and tin may be injected through the first gas flow path 4a. In this case, the first gas flow path 4a may be connected with the source supply unit 5. The reactant gas including oxide may be injected through the second gas flow path 4b. In this case, the second gas flow path 4b may be connected with the reactant supply unit 8. The reactant gas including oxide may be injected through the third gas flow path. In this case, the third gas flow path may be connected with the reactant supply unit 8. When the metal oxide semiconductor 200 is a three-dimensional transistor, the d) step (S40) may be performed by forming the first channel layer 231 on a side surface of the second channel layer 232.

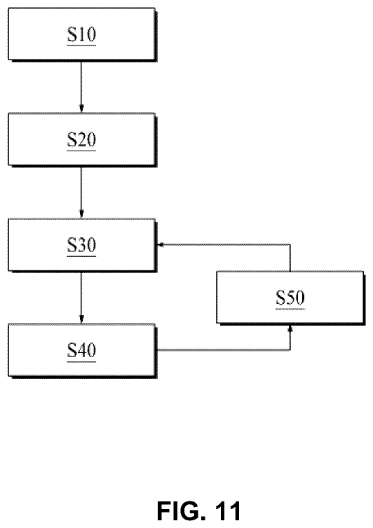

Referring to FIGS. 2 to 11, the method of manufacturing metal oxide semiconductor according to the present invention may further include a step (S50 illustrated in FIG. 11) of repeatedly performing the c) step after performing the d) step. Through the step (S50), the first channel layer 231 and the second channel layer 232 may be alternately formed in the order of the first channel layer 231, the second channel layer 232, the first channel layer 231, and the second channel layer 232. The step (S50 illustrated in FIG. 11) of repeatedly performing the c) step after performing the d) step may be repeatedly performed until the oxide layer 230 is formed on the exposed surface 211 to have a predetermined thickness.

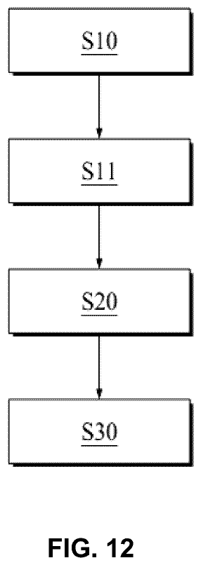

Referring to FIGS. 2 to 12, the method of manufacturing metal oxide semiconductor according to the present invention may include a step (S11 illustrated in FIG. 12) of performing treatment the exposed surface. The step (S11) may be performed before performing the b) step (S20). The method of manufacturing metal oxide semiconductor according to the present invention may be implemented to form the first channel layer 231 on the exposed surface 211 after treatment on the exposed surface 211 is performed, and thus, may more enhance a step coverage of the first channel layer 231. The step (S11) of performing treatment on the exposed surface may be performed by the injection unit 4.

The step (S11) of performing treatment on the exposed surface may be performed by performing treatment on the exposed surface 211 with plasma using at least one of ozone (O₃), hydrogen (H₂), and ammonia (NH₃). In this case, the injection unit 4 may perform treatment on the exposed surface 211 by using plasma, generated by using the second plate 42 and the first plate 41, and at least one of ozone (O₃), hydrogen (H₂), and ammonia (NH₃).

The step (S11) of performing treatment on the exposed surface may be performed by performing treatment on the exposed surface 211 on the basis of a thermal treatment process at an oxygen (O₂) atmosphere. In this case, the injection unit 4 may implement the processing space 100 having an oxygen atmosphere and a heating unit (not shown) may provide heat, and thus, the step (S11) of performing treatment on the exposed surface may be performed. The heating unit may be installed in at least one of the lid and the substrate supporting unit 3.

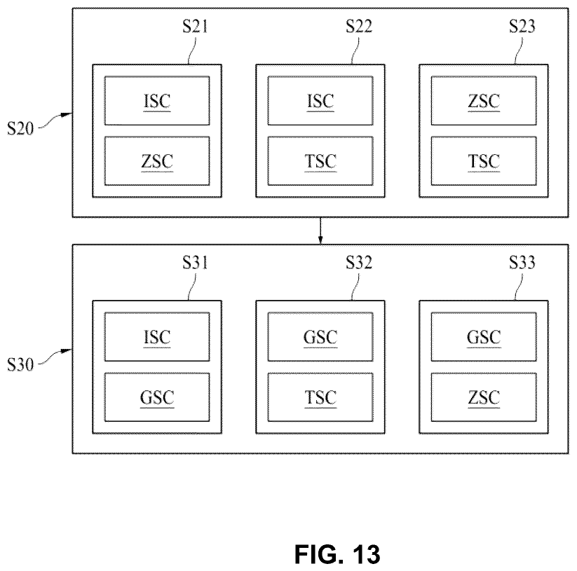

Referring to FIGS. 2 to 13, in a method of manufacturing metal oxide semiconductor according to a modified embodiment of the present invention, the b) step (S20) and the c) step (S30) may be implemented as follows.

The b) step (S20) may be performed by forming the first channel layer 231 by using at least one of indium zinc oxide (IZO), indium tin oxide (ITO), and zinc tin oxide (ZTO).

The b) step (S20) may include a step (S21) of depositing indium zinc oxide. The step (S21) of depositing the indium zinc oxide may be performed by sequentially performing an indium oxide sub-cycle (ISC) and a zinc oxide sub-cycle (ZSC).

The indium oxide sub-cycle (ISC) may sequentially perform injection of a source gas including indium and injection of a reactant gas including oxide to deposit the indium oxide through an ALD process. The indium oxide sub-cycle (ISC) may sequentially perform injection of a source gas including indium and injection of a reactant gas including oxide to deposit the indium oxide through an ALD process. The source gas including indium may be injected through the first gas flow path 4a. In this case, the first gas flow path 4a may be connected with the source supply unit 5. The reactant gas including oxide may be injected through the second gas flow path 4b. In this case, the second gas flow path 4b may be connected with the reactant supply unit 8. The reactant gas including oxide may be injected through the third gas flow path. In this case, the third gas flow path may be connected with the reactant supply unit 8.

The zinc oxide sub-cycle (ZSC) may sequentially perform injection of a source gas including zinc and injection of a reactant gas including oxide to deposit the zinc oxide through an ALD process. The indium oxide sub-cycle (ISC) may sequentially perform injection of a source gas including zinc and injection of a reactant gas including oxide a plurality of times to deposit the zinc oxide through an ALD process. The source gas including zinc may be injected through the first gas flow path 4a. In this case, the first gas flow path 4a may be connected with the source supply unit 5. The reactant gas including oxide may be injected through the second gas flow path 4b. In this case, the second gas flow path 4b may be connected with the reactant supply unit 8. The reactant gas including oxide may be injected through the third gas flow path. In this case, the third gas flow path may be connected with the reactant supply unit 8.

The step (S21) of depositing the indium zinc oxide by sequentially performing the indium oxide sub-cycle (ISC) and the zinc oxide sub-cycle (ZSC) may sequentially deposit the indium oxide and the zinc oxide on the exposed surface 211 to form the indium zinc oxide (IZO) on the exposed surface 211. The indium zinc oxide (IZO) may configure all of the first channel layer 231 or a portion of the first channel layer 231. The step (S21) of depositing the indium zinc oxide may be performed by sequentially performing the indium oxide sub-cycle (ISC) and the zinc oxide sub-cycle (ZSC) a plurality of times.

The b) step (S20) may include a step (S22) of depositing indium tin oxide. The step (S22) of depositing the indium tin oxide may be performed by sequentially performing the indium oxide sub-cycle (ISC) and a tin oxide sub-cycle (TSC). The indium oxide sub-cycle (ISC) is implemented to approximately match the description of the step (S21) of depositing the indium zinc oxide, and thus, a detailed description thereof is omitted.

The tin oxide sub-cycle (TSC) may sequentially perform injection of a source gas including tin and injection of a reactant gas including oxide to deposit the tin oxide through an ALD process. The tin oxide sub-cycle (TSC) may sequentially perform injection of a source gas including tin and injection of a reactant gas including oxide a plurality of times to deposit the tin oxide through an ALD process. The source gas including tin may be injected through the first gas flow path 4a. In this case, the first gas flow path 4a may be connected with the source supply unit 5. The reactant gas including oxide may be injected through the second gas flow path 4b. The second gas flow path 4b may be connected with the reactant supply unit 8. The reactant gas including oxide may be injected through the third gas flow path. In this case, the third gas flow path may be connected with the reactant supply unit 8.

The step (S22) of depositing the indium tin oxide by sequentially performing the indium oxide sub-cycle (ISC) and the tin oxide sub-cycle (TSC) may sequentially deposit the indium oxide and the tin oxide on the exposed surface 211 to form the indium tin oxide (ITO) on the exposed surface 211. The indium tin oxide (ITO) may configure all of the first channel layer 231 or a portion of the first channel layer 231. The step (S22) of depositing the indium tin oxide may be performed by sequentially performing the indium oxide sub-cycle (ISC) and the tin oxide sub-cycle (TSC) a plurality of times.

The b) step (S20) may include a step (S23) of depositing zinc tin oxide. The step (S23) of depositing the zinc tin oxide may be performed by sequentially performing the zinc oxide sub-cycle (ZSC) and the tin oxide sub-cycle (TSC). The zinc oxide sub-cycle (ZSC) is implemented to approximately match the description of the step (S21) of depositing the indium zinc oxide and the tin oxide sub-cycle (TSC) is implemented to approximately match the description of the step (S22) of depositing the indium tin oxide, and thus, detailed descriptions thereof are omitted. The step (S23) of depositing the zinc tin oxide by sequentially performing the zinc oxide sub-cycle (ZSC) and the tin oxide sub-cycle (TSC) may sequentially deposit the zinc oxide and the tin oxide on the exposed surface 211 to form the zinc tin oxide (ZTO) on the exposed surface 211. The zinc tin oxide (ZTO) may configure all of the first channel layer 231 or a portion of the first channel layer 231. The step (S23) of depositing the zinc tin oxide may be performed by sequentially performing the zinc oxide sub-cycle (ZSC) and the tin oxide sub-cycle (TSC) a plurality of times.

Moreover, the b) step (S20) may include at least one of the step (S21) of depositing the indium zinc oxide, the step (S22) of depositing the indium tin oxide, and the step (S23) of depositing the zinc tin oxide.

The c) step (S30) may be performed by forming the second channel layer 232 by using at least one of indium gallium oxide (IGO), gallium tin oxide (GTO), and gallium zinc oxide (GZO).

The c) step (S30) may include a step (S31) of depositing indium gallium oxide. The step (S31) of depositing the indium gallium oxide may be performed by sequentially performing the indium oxide sub-cycle (ISC) and a gallium oxide sub-cycle (GSC). The indium oxide sub-cycle (ISC) is implemented to approximately match the description of the step (S21) of depositing the indium zinc oxide in the b) step (S20), and thus, a detailed description thereof is omitted.

The gallium oxide sub-cycle (GSC) may sequentially perform injection of a source gas including gallium and injection of a reactant gas including oxide to deposit the gallium oxide through an ALD process. The gallium oxide sub-cycle (GSC) may sequentially perform injection of a source gas including gallium and injection of a reactant gas including oxide a plurality of times to deposit the gallium oxide through an ALD process. The source gas including gallium may be injected through the first gas flow path 4a. In this case, the first gas flow path 4a may be connected with the source supply unit 5. The reactant gas including oxide may be injected through the second gas flow path 4b. In this case, the second gas flow path 4b may be connected with the reactant supply unit 8. The reactant gas including oxide may be injected through the third gas flow path. In this case, the third gas flow path may be connected with the reactant supply unit 8.

The step (S31) of depositing the indium gallium oxide by sequentially performing the indium oxide sub-cycle (ISC) and the gallium oxide sub-cycle (GSC) may sequentially deposit the indium oxide and the gallium oxide on the first channel layer 231 to form the indium gallium oxide (IGO) on the first channel layer 231. The indium gallium oxide (IGO) may configure all of the second channel layer 232 or a portion of the second channel layer 232. The step (S31) of depositing the indium gallium oxide may be performed by sequentially performing the indium oxide sub-cycle (ISC) and the gallium oxide sub-cycle (GSC) a plurality of times.

The c) step (S30) may include a step (S32) of depositing gallium tin oxide. The step (S32) of depositing the gallium tin oxide may be performed by sequentially performing the gallium oxide sub-cycle (GSC) and the tin oxide sub-cycle (TSC). The gallium oxide sub-cycle (GSC) is implemented to approximately match the description of the step (S31) of depositing the indium gallium oxide and the tin oxide sub-cycle (TSC) is implemented to approximately match the description of the step (S22) of depositing the indium tin oxide in the b) step (S20), and thus, detailed descriptions thereof are omitted.

The step (S32) of depositing the gallium tin oxide by sequentially performing the gallium oxide sub-cycle (GSC) and the tin oxide sub-cycle (TSC) may sequentially deposit the gallium oxide and the tin oxide on the first channel layer 231 to form the gallium tin oxide (GTO) on the first channel layer 231. The gallium tin oxide (GTO) may configure all of the second channel layer 232 or a portion of the second channel layer 232. The step (S32) of depositing the gallium tin oxide may be performed by sequentially performing the gallium oxide sub-cycle (GSC) and the tin oxide sub-cycle (TSC) a plurality of times.

The c) step (S30) may include a step (S33) of depositing gallium zinc oxide. The step (S33) of depositing the gallium zinc oxide may be performed by sequentially performing the gallium oxide sub-cycle (GSC) and the zinc oxide sub-cycle (ZSC). The gallium oxide sub-cycle (GSC) is implemented to approximately match the description of the step (S31) of depositing the indium gallium oxide and the zinc oxide sub-cycle (ZSC) is implemented to approximately match the description of the step (S21) of depositing the indium zinc oxide in the b) step (S20), and thus, detailed descriptions thereof are omitted.

The step (S33) of depositing the gallium zinc oxide by sequentially performing the gallium oxide sub-cycle (GSC) and the zinc oxide sub-cycle (ZSC) may sequentially deposit the gallium oxide and the zinc oxide on the first channel layer 231 to form the gallium zinc oxide (GZO) on the first channel layer 231. The gallium zinc oxide (GZO) may configure all of the second channel layer 232 or a portion of the second channel layer 232. The step (S33) of depositing the gallium zinc oxide may be performed by sequentially performing the gallium oxide sub-cycle (GSC) and the zinc oxide sub-cycle (ZSC) a plurality of times.

Moreover, the c) step (S30) may include at least one of the step (S31) of depositing the indium gallium oxide, the step (S32) of depositing the gallium tin oxide, and the step (S33) of depositing the gallium zinc oxide.

Referring to FIGS. 2 to 13, a method of manufacturing metal oxide semiconductor according to a modified embodiment of the present invention may include a step of repeatedly performing the c) step (S30) after repeatedly performing the b) step (S20). In this case, the first channel layer 231 may be formed of a plurality of layers on the exposed surface 211 by repeatedly performing the b) step (S20), and then, the second channel layer 232 may be formed of a plurality of layers on the first channel layer 231 by repeatedly performing the c) step (S30). A step of repeatedly performing the c) step after repeatedly performing the b) step may be repeatedly performed until the oxide layer 230 is formed on the exposed surface 211 to have a predetermined thickness.

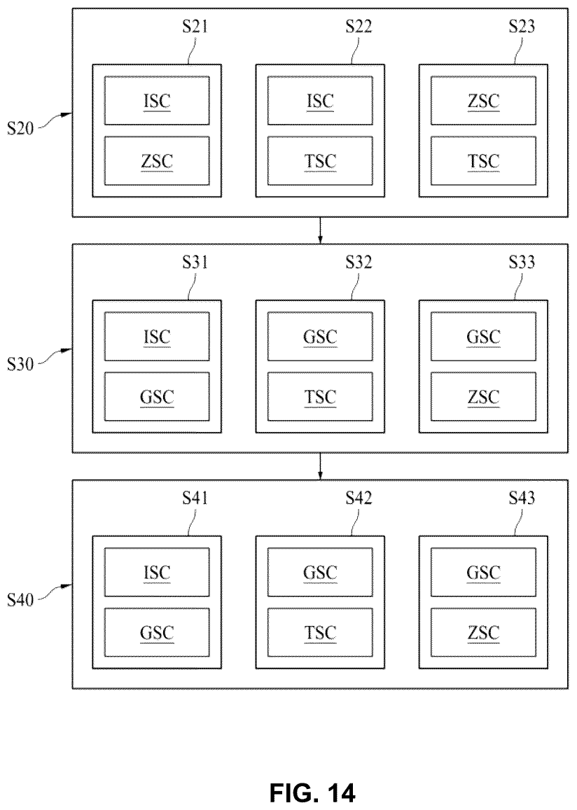

Referring to FIGS. 2 to 14, a method of manufacturing metal oxide semiconductor according to a modified embodiment of the present invention may further include the d) step (S40).

The d) step (S40) may be performed by forming the first channel layer 231 by using at least one of indium zinc oxide (IZO), indium tin oxide (ITO), and zinc tin oxide (ZTO).

The d) step (S40) may include a step (S41) of depositing indium zinc oxide. The step (S41) of depositing the indium zinc oxide may be performed by sequentially performing the indium oxide sub-cycle (ISC) and the zinc oxide sub-cycle (ZSC). The step (S41) of depositing the indium zinc oxide by sequentially performing the indium oxide sub-cycle (ISC) and the zinc oxide sub-cycle (ZSC) may sequentially deposit the indium oxide and the zinc oxide on the second channel layer 232 to form the indium zinc oxide (IZO) on the second channel layer 232. The indium zinc oxide (IZO) may configure all of the first channel layer 231 or a portion of the first channel layer 231. The step (S41) of depositing the indium zinc oxide may be performed by sequentially performing the indium oxide sub-cycle (ISC) and the zinc oxide sub-cycle (ZSC) a plurality of times.

The d) step (S40) may include a step (S42) of depositing indium tin oxide. The step (S42) of depositing the indium tin oxide may be performed by sequentially performing the indium oxide sub-cycle (ISC) and the tin oxide sub-cycle (TSC). The step (S42) of depositing the indium tin oxide by sequentially performing the indium oxide sub-cycle (ISC) and the tin oxide sub-cycle (TSC) may sequentially deposit the indium oxide and the tin oxide on the second channel layer 232 to form the indium tin oxide (ITO) on the second channel layer 232. The indium tin oxide (ITO) may configure all of the first channel layer 231 or a portion of the first channel layer 231. The step (S42) of depositing the indium tin oxide may be performed by sequentially performing the indium oxide sub-cycle (ISC) and the tin oxide sub-cycle (TSC) a plurality of times.

The d) step (S40) may include a step (S43) of depositing zinc tin oxide. The step (S43) of depositing the zinc tin oxide may be performed by sequentially performing the zinc oxide sub-cycle (ZSC) and the tin oxide sub-cycle (TSC). The step (S43) of depositing the zinc tin oxide by sequentially performing the zinc oxide sub-cycle (ZSC) and the tin oxide sub-cycle (TSC) may sequentially deposit the zinc oxide and the tin oxide on the second channel layer 232 to form the zinc tin oxide (ZTO) on the second channel layer 232. The zinc tin oxide (ZTO) may configure all of the first channel layer 231 or a portion of the first channel layer 231. The step (S43) of depositing the zinc tin oxide may be performed by sequentially performing the zinc oxide sub-cycle (ZSC) and the tin oxide sub-cycle (TSC) a plurality of times.

Moreover, the d) step (S40) may include at least one of the step (S41) of depositing the indium zinc oxide, the step (S42) of depositing the indium tin oxide, and the step (S43) of depositing the zinc tin oxide.

Referring to FIGS. 2 to 14, the method of manufacturing metal oxide semiconductor according to a modified embodiment of the present invention may further include a step (S50 illustrated in FIG. 11) of repeatedly performing the c) step after performing the d) step. Through the step (S50), the first channel layer 231 and the second channel layer 232 may be alternately formed in the order of the first channel layer 231, the second channel layer 232, the first channel layer 231, and the second channel layer 232. The step (S50) of repeatedly performing the c) step after performing the d) step may be repeatedly performed until the oxide layer 230 is formed on the exposed surface 211 to have a predetermined thickness.

The present invention described above are not limited to the above-described embodiments and the accompanying drawings and those skilled in the art will clearly appreciate that various modifications, deformations, and substitutions are possible without departing from the scope and spirit of the invention.

1. A substrate processing apparatus comprising:
a chamber;
a substrate supporting unit disposed in the chamber;
an injection unit disposed above the substrate supporting unit;
a first source supply unit for supplying a first source gas;
a second source supply unit for supplying a second source gas;
a first supply line connecting the first source supply unit with the injection unit;
a second supply line connecting the second source supply unit with the injection unit;
a mixing unit installed in the first supply line so as to be disposed between the first source supply unit and the injection unit;
a first connection line connecting the second supply line with at least one of the first supply line and the mixing unit; and
a first path change unit installed at a first connection point at which the first connection line is connected with the second supply line,
wherein the first path change unit changes a flow path of the second source gas so that the second source gas supplied from the second source supply unit is supplied to one selected from among the mixing unit and the injection unit.

2. The substrate processing apparatus of claim 1, wherein, in a case where the injection unit injects a mixed gas, where a plurality of source gases are mixed with one another, toward the substrate to perform a processing process, the first path change unit changes the flow path of the second source gas so that the second source gas is supplied to the mixing unit.

3. The substrate processing apparatus of claim 1, wherein, in a case where the injection unit sequentially injects a plurality of source gases toward the substrate to perform a processing process, the first path change unit changes the flow path of the second source gas so that the second source gas is supplied to the injection unit.

4. The substrate processing apparatus of one of claims 1 to 3claim 1, wherein the first path change unit comprises:
a first connection valve selectively opening or closing the first connection line; and
a first supply valve selectively opening or closing the second supply line.

5. The substrate processing apparatus of claim 1, further comprising:
a first mixing valve installed in the first supply line so as to be disposed between the first source supply unit and the mixing unit; and
a second mixing valve installed in the first supply line so as to be disposed between the mixing unit and the injection unit.

6. The substrate processing apparatus of claim 1, comprising an inter-purge unit connected with the mixing unit,
wherein the injection unit injects a mixed gas, where a plurality of source gases are mixed with one another, toward the substrate to perform a first processing process, and then, sequentially injects a plurality of source gases toward the substrate to perform a second processing process, and
before only the first source gas is supplied to the mixing unit so as to perform the second processing process after the first processing process is performed, the inter-purge unit supplies a purge gas, which purges an inner portion of the mixing unit, to the mixing unit.

7. The substrate processing apparatus of claim 1, further comprising:
a third source supply unit for supplying a third source gas;
a third supply line connecting the third source supply unit with the injection unit;
a second connection line connecting the third supply line with at least one of the first supply line and the mixing unit; and
a second path change unit installed at a second connection point at which the second connection line is connected with the third supply line,
wherein the second path change unit changes a flow path of the third source gas so that the third source gas supplied from the third source supply unit is supplied to one selected from among the mixing unit and the injection unit.

8. The substrate processing apparatus of claim 1, further comprising a reactant supply unit for supplying a reactant gas to the injection unit.

9. A method of manufacturing a metal oxide semiconductor of an oxide layer on an exposed surface of a thin film, the method comprising:
a) step of preparing a substrate where the exposed surface of the thin film is patterned;
b) step of forming a first channel layer on the exposed surface by using at least one of indium oxide (InO), zinc oxide (ZnO), and tin oxide (SnO); and
c) step of forming a second channel layer by using gallium oxide (GaO).

10. The method for manufacturing a metal oxide semiconductor of claim 9, further comprising a step of repeatedly performing the c) step after repeatedly performing the b) step.

11. The method for manufacturing a metal oxide semiconductor of claim 9, further comprising d) step of forming the first channel layer on the second channel layer by using at least one of indium oxide, zinc oxide, and tin oxide.

12. The method for manufacturing a metal oxide semiconductor of claim 11, further comprising a step of repeatedly performing the c) step after performing the d) step.

13. The method for manufacturing a metal oxide semiconductor of claim 9, further comprising a step of performing treatment on the exposed surface, before performing the b) step.

14. The method for manufacturing a metal oxide semiconductor of claim 13, wherein the step of performing treatment on the exposed surface performs treatment with plasma using at least one of ozone (O₃), hydrogen (H₂), and ammonia (NH₃).

15. The method for manufacturing a metal oxide semiconductor of claim 13, wherein the step of performing treatment on the exposed surface performs treatment through a thermal treatment process at an oxygen (O₂) atmosphere.

16. The method for manufacturing a metal oxide semiconductor of claim 9, wherein the b) step forms the first channel layer by using at least one of indium zinc oxide (IZO), indium tin oxide (ITO), and zinc tin oxide (ZTO), and
the c) step forms the second channel layer by using at least one of indium gallium oxide (IGO), gallium tin oxide (GTO), and gallium zinc oxide (GZO).

17. The method for manufacturing a metal oxide semiconductor of claim 16, further comprising a step of repeatedly performing the c) step after repeatedly performing the b) step.

18. The method for manufacturing a metal oxide semiconductor of claim 16, further comprising d) step of forming the first channel layer on the second channel layer by using at least one of indium zinc oxide (IZO), indium tin oxide (ITO), and zinc tin oxide (ZTO).

19. The method for manufacturing a metal oxide semiconductor of claim 18, further comprising a step of repeatedly performing the c) step after performing the d) step.
